(19) United States
(12) Patent Application Publication
(10) Pub. No.: US 2024/0210820 A1
(43) Pub. Date: Jun. 27, 2024

(54) IMPRINT APPARATUS, IMPRINT METHOD AND ARTICLE MANUFACTURING METHOD

(71) Applicant: CANON KABUSHIKI KAISHA, Tokyo (JP)

(72) Inventor: Keisuke KIMURA, Tochigi (JP)

(21) Appl. No.: 18/535,137

(22) Filed: Dec. 11, 2023

(30) Foreign Application Priority Data
Dec. 26, 2022 (JP) 2022-208799

(51) Int. Cl. G03F 7/00; B29C 43/58; B29C 59/00

(52) U.S. Cl. CPC G03F 7/0017; B29C 43/58; B29C 59/007; B29C 2043/563

(57) ABSTRACT

An imprint apparatus including a mold holding unit configured to hold a mold, an adjusting unit configured to adjust a pressure difference between a first pressure on a second surface on an opposite side of a first surface on which a pattern of the mold held by the mold holding unit is formed and a second pressure in a first space between a substrate and the first surface of the mold, and a control unit configured to control an imprint process, wherein the imprint process includes a separation process of separating the mold from a pattern made of a cured product of an imprint material on the substrate, and the control unit controls, in the separation process, the adjustment of the pressure difference by the adjusting unit so that the first pressure is smaller than the second pressure.

### BACKGROUND

### Field of the Invention

The present invention relates to an imprint apparatus, an imprint method and an article manufacturing method.

### Description of the Related Art

There is known an imprint apparatus for forming a pattern of an imprint material on a substrate by arranging (supplying) the imprint material on the substrate and curing the imprint material while forming the imprint material by a mold (in a state in which the imprint material and the mold are in contact with each other).

The imprint apparatus performs an imprint process including a contact step of bringing the imprint material on the substrate and the mold (a pattern thereof) into contact with each other, a curing step of curing the imprint material on the substrate, and a separation step of separating (releasing) the mold from the cured imprint material on the substrate.

In the imprint process, in the separation step, the mold may be detached (come off) from a mold holding mechanism, that is, dechucking may occur. To cope with this, with respect to the imprint apparatus, a technique of suppressing dechucking is proposed in Japanese Patent No. 5744423.

However, in the conventional technique, in the separation step, in a case where a bonding force between the mold and the cured imprint material (cured product) on the substrate is relatively strong, it may be impossible to separate the cured product and the mold, thereby causing dechucking.

### SUMMARY OF THE INVENTION

The present invention provides a technique advantageous in suppressing a mold from being detached from a mold holding unit when separating the mold from a pattern made of a cured product of an imprint material on a substrate.

According to one aspect of the present invention, there is provided an imprint apparatus for performing an imprint process of forming a pattern made of a cured product of an imprint material on a substrate using a mold, including a mold holding unit configured to hold the mold, an adjusting unit configured to adjust a pressure difference between a first pressure on a second surface on an opposite side of a first surface on which a pattern of the mold held by the mold holding unit is formed and a second pressure in a first space between the substrate and the first surface of the mold, and a control unit configured to control the imprint process, wherein the imprint process includes a separation process of separating the mold from the pattern made of the cured product of the imprint material, and the control unit controls, in the separation process, the adjustment of the pressure difference by the adjusting unit so that the first pressure is smaller than the second pressure.

Further aspects of the present invention will become apparent from the following description of exemplary embodiments with reference to the attached drawings.

### BRIEF DESCRIPTION OF THE DRAWINGS

FIG. 1 is a schematic view illustrating configurations of an imprint apparatus according to an aspect of the present invention.

FIGS. 2A to 2E are views schematically illustrating respective processes of an imprint process.

FIG. 3 is a view schematically illustrating forces acting in a separation step.

FIG. 4 is a view illustrating the arrangement of a mold suction mechanism and a pressure adjusting mechanism.

FIG. 5 is a view illustrating the arrangement of a mold positioning mechanism of a mold driving mechanism.

FIG. 6 is a view illustrating the arrangement of a gas supply mechanism.

FIGS. 7A and 7B are views each illustrating a pattern surface of a mold.

FIGS. 8A to 8F are views for describing an article manufacturing method.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

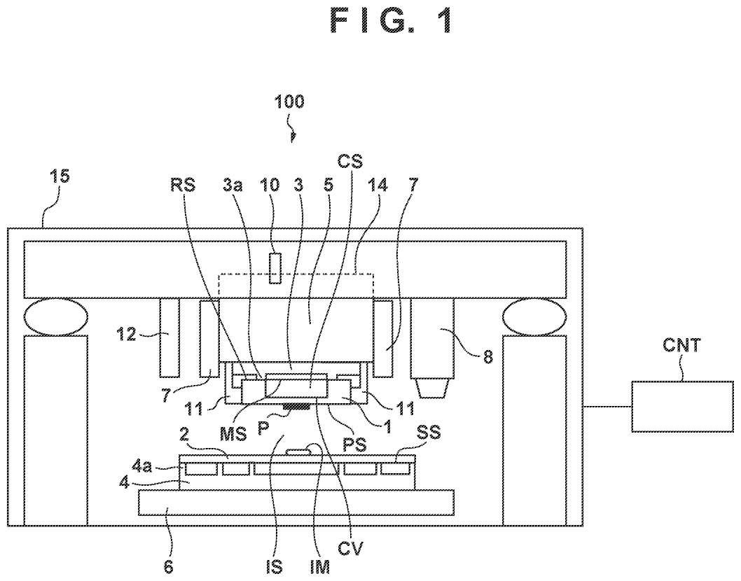

FIG. 1 is a schematic view illustrating configurations of an imprint apparatus 100 according to an aspect of the present invention. The imprint apparatus 100 is a lithography apparatus employed in a lithography step that is a manufacturing step for a device such as a semiconductor element, a liquid crystal display element, or magnetic storage medium as an article to form a pattern on a substrate. The imprint apparatus 100 brings an uncured imprint material arranged (supplied) on the substrate into contact with the mold, and applies curing energy to the imprint material, thereby forming a pattern of a cured product to which the pattern of the mold is transferred.

As the imprint material, a material (curable composition) to be cured by receiving curing energy is used. An example of the curing energy that is used is electromagnetic waves, heat, or the like. As the electromagnetic waves, for example, infrared light, visible light, ultraviolet light, and the like selected from the wavelength range of 10 nm (inclusive) to 1 mm (inclusive) is used.

The curable composition is a composition cured by light irradiation or heating. The photo-curable composition cured by light irradiation contains at least a polymerizable compound and a photopolymerization initiator, and may contain a nonpolymerizable compound or a solvent, as needed. The nonpolymerizable compound is at least one type of material selected from a group comprising of a sensitizer, a hydrogen donor, an internal mold release agent, a surfactant, an antioxidant, a polymer component, and the like.

The imprint material may be applied in a film shape onto the substrate by a spin coater or a slit coater. The imprint material may be applied, onto the substrate, in a droplet shape or in an island or film shape formed by connecting a plurality of droplets using a liquid injection head. The viscosity (the viscosity at 25° C.) of the imprint material is, for example, 1 mPa·s (inclusive) to 100 mPa·s (inclusive).

As the substrate, glass, ceramic, a metal, a semiconductor, a resin, or the like is used, and a member made of a material different from that of the substrate may be formed on the surface of the substrate, as needed. More specifically, examples of the substrate include a silicon wafer, a semiconductor compound wafer, silica glass, and the like.

In the specification and the accompanying drawings, directions will be indicated on an XYZ coordinate system in which directions parallel to a plane on which the substrate is placed are defined as the X-Y plane. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are θX, θY, and θZ, respectively.

The imprint apparatus 100 may adopt, as a method of curing an imprint material, a photo-curing method of curing an imprint material by irradiating it with light such as ultraviolet light, or a heat-curing method of curing an imprint material by applying heat.

The imprint apparatus 100 includes a substrate holding unit 4 that includes a substrate holding surface SS for holding a substrate 2, and a substrate driving mechanism 6 that moves the substrate 2 by driving the substrate holding unit 4. The substrate driving mechanism 6 has a function of driving the substrate holding unit 4 with respect to six axes that are the X-axis, the Y-axis, the Z-axis, and rotations about these axes. In this embodiment, the substrate holding unit 4 includes a plurality of pins (not shown), at least one ring-shaped projecting portion 4a for substrate suction that is formed on the inner and outer peripheries of the plurality of pins, and a suction hole (not shown), and is formed by a vacuum suction chuck that holds the substrate 2 by vacuum suction. However, the substrate holding unit 4 may be formed by a porous chuck made of a porous material or an electrostatic chuck including an electrode.

The imprint apparatus 100 includes a measuring device (not shown) such as a laser interferometer or an encoder that measures the position of the substrate holding unit 4 or the substrate 2. Based on the measurement result of the measuring device, a control unit CNT controls the position of the substrate holding unit 4 or the substrate 2 via the substrate driving mechanism 6.

The imprint apparatus 100 includes a mold holding unit 3 that includes a mold holding surface MS for holding a mold 1, a mold driving mechanism 5 that moves the mold 1 by driving the mold holding unit 3, and a mold pressing mechanism 11. The mold driving mechanism 5 has a function of driving the mold holding unit 3 with respect to six axes that are the X-axis, the Y-axis, the Z-axis, and rotations about these axes. In this embodiment, the mold holding unit 3 includes a plurality of pins (not shown), at least one ring-shaped projecting portion 3a for mold suction that is formed on the inner and outer peripheries of the plurality of pins, and a suction hole (not shown), and is formed by a vacuum suction chuck that holds the mold 1 by vacuum suction. However, the mold holding unit 3 may be formed by a porous chuck made of a porous material or an electrostatic chuck including an electrode.

In this embodiment, the mold driving mechanism 5 and the substrate driving mechanism 6 function as driving mechanisms that relatively drive the mold holding unit 3 (mold 1) and the substrate holding unit 4 (substrate 2). More specifically, the mold driving mechanism 5 and the substrate driving mechanism 6 relatively drive the mold holding unit 3 and the substrate holding unit 4 in a direction (first direction) in which the mold holding unit 3 and the substrate holding unit 4 move close to or away from each other, that is, in the Z direction. Furthermore, the mold driving mechanism 5 and the substrate driving mechanism 6 relatively drive the mold holding unit 3 and the substrate holding unit 4 in a direction (second direction) along the mold holding surface MS and the substrate holding surface SS, that is, a direction along the X direction and the Y direction (X-Y plane). In addition, the mold driving mechanism 5 and the substrate driving mechanism 6 relatively rotate the mold holding unit 3 and the substrate holding unit 4 about an axis orthogonal to the direction along the mold holding surface MS and the substrate holding surface SS, that is, the Z-axis. In this example, an operation of relatively driving the mold holding unit 3 and the substrate holding unit 4 includes an operation of driving the substrate holding unit 4 in a state in which the mold holding unit 3 stays still, and an operation of driving the mold holding unit 3 in a state in which the substrate holding unit 4 stays still. Furthermore, an operation of relatively driving the substrate holding unit 4 with respect to the mold holding unit 3 also includes an operation of driving both the mold holding unit 3 and the substrate holding unit 4 so that the relative position between the mold holding unit 3 and the substrate holding unit 4 changes.

The mold 1 has a rectangular outer shape, and includes a pattern surface PS (a first surface on which a pattern P of the mold 1 is formed) on which the pattern P (for example, a concave-convex pattern such as a circuit pattern) to be transferred to the substrate 2 (an imprint material IM thereon) is three-dimensionally formed. In this embodiment, the mold 1 is formed such that the thickness of a portion where the pattern P is formed is smaller than the thickness of the peripheral portion of the pattern P, and has such concave structure that the central portion of a surface RS (second surface) on the opposite side of the pattern surface PS is concave, that is, a concave portion CV (cavity). Note that the pattern surface PS of the mold 1, more specifically, the surface of the pattern P is preferably processed with high surface accuracy to maintain the adherence with the imprint material IM on the substrate. The mold 1 is made of a material that can transmit energy, for example, ultraviolet light, emitted from a curing unit 14, and is made of, more particularly, silica glass or the like.

A space defined by the mold holding surface MS and the concave portion CV of the mold 1 when the mold holding unit 3 holds the surface RS of the substrate 2 by the mold holding surface MS will be referred to as a cavity space CS (a second space on the side of the surface RS of the mold 1) hereinafter. The imprint apparatus 100 has a pressure adjusting mechanism PA (see FIG. 4) for adjusting a pressure in the cavity space CS defined by the mold holding surface MS and the concave portion CV of the mold 1. In this embodiment, the pressure adjusting mechanism PA functions as one adjusting unit that adjusts a pressure difference between a pressure (first pressure) on the surface RS of the mold 1 and a pressure (second pressure) in an imprint space IS (first space) defined between the substrate 2 and the pattern surface PS of the mold 1.

Adjustment of the pressure in the cavity space CS means adjustment of the force or pressure applied to the concave portion CV of the mold 1. By adjusting the pressure in the cavity space CS, it is possible to adjust distortion (deformation) of the pattern P formed in the central portion of the mold 1. For example, by adjusting the pressure in the cavity space CS to a pressure higher than the pressure in the imprint space IS, it is possible to deform the pattern P of the mold 1 into a convex shape toward the substrate 2 in a contact process of bringing the mold 1 and the imprint material IM on the substrate into contact with each other.

The mold pressing mechanism 11 is arranged to surround the side surfaces of the mold 1 held by the mold holding unit 3. The mold pressing mechanism 11 includes a finger that functions as a pressing member for pressing the side surface of the mold 1, and a piezoelectric actuator that drives the finger, and presses each side surface of the mold 1 to deform the mold 1 into a desired shape. In this embodiment, fingers the number of which is equal to the number of side surfaces of the mold 1 are arranged for the respective fingers, and are arranged to contact the respective side surfaces of the mold 1 in a state in which the mold holding unit 3 holds the mold 1. When the mold pressing mechanism 11 is used to deform the mold 1, the shape of a pattern region where the pattern P of the mold 1 is formed can be made close to the shape of a region (imprint region) where the pattern on the substrate is to be formed. A shape difference between the imprint region on the substrate and the pattern region of the mold 1 is generated by, for example, a manufacturing error of the mold 1 or thermal deformation of the substrate 2.

The imprint apparatus 100 includes an arrangement mechanism 8 (dispenser) that arranges the imprint material IM on the substrate. However, the arrangement mechanism 8 may be formed as an external apparatus of the imprint apparatus 100. The arrangement mechanism 8 arranges the imprint material IM in a shot region of the substrate 2. The imprint material IM is arranged in a shot region of the substrate 2 when, in a state in which the substrate driving mechanism 6 drives the substrate 2, the arrangement mechanism 8 discharges the imprint material IM in synchronism with the driving.

In this embodiment, every time the arrangement mechanism 8 arranges the imprint material IM in one shot region of the substrate 2, a contact process and a separation process of separating the mold 1 from the pattern made of a cured product of the imprint material IM on the substrate are executed. Note that after the arrangement mechanism 8 arranges the imprint material IM in a plurality of shot regions of the substrate 2, the contact process and the separation process may be executed for each of the plurality of shot regions where the imprint material IM is arranged.

The imprint apparatus 100 includes the curing unit 14 that cures the imprint material by applying energy to the imprint material IM arranged on the substrate. The curing unit 14 applies energy, for example, light (ultraviolet light) or heat, for curing the imprint material IM in a state in which the imprint material IM on the substrate and the mold 1 (the pattern surface PS thereof) are in contact with each other.

The inner space of the imprint apparatus 100, more specifically, the imprint space IS between the mold 1 and the substrate 2 may be replaced by a gas other than air. For example, when curing the imprint material IM by bringing the imprint material IM on the substrate and the mold 1 into contact with each other, it is possible to reduce a defect of the pattern formed on the substrate by replacing the atmosphere around the pattern surface PS of the mold 1 by a gas other than air. Examples of the gas are helium, nitrogen, and various kinds of functional gases. The imprint apparatus 100 includes an environment management unit 7 to replace a gas in the imprint space IS. The environment management unit 7 includes, for example, a supply unit that supplies a gas to the imprint space IS, and a suction unit that sucks the gas from the imprint space IS.

The imprint apparatus 100 includes an alignment scope 10 and an off-axis scope 12. The alignment scope 10 measures the position of a mark provided on the substrate 2, the position of a mark provided on the mold 1, and the relative position between the mark provided on the substrate 2 and the mark provided on the mold 1. The off-axis scope 12 measures the position of the mark provided on the substrate 2.

The imprint apparatus 100 includes the control unit CNT formed by a computer (information processing apparatus) including a CPU and a memory. The control unit CNT operates the imprint apparatus 100 by comprehensively controlling the respective units of the imprint apparatus 100 in accordance with a program stored in a storage unit. In this embodiment, the control unit CNT controls an imprint process (imprint method) of forming a pattern made of a cured product of the imprint material IM on the substrate using the mold 1.

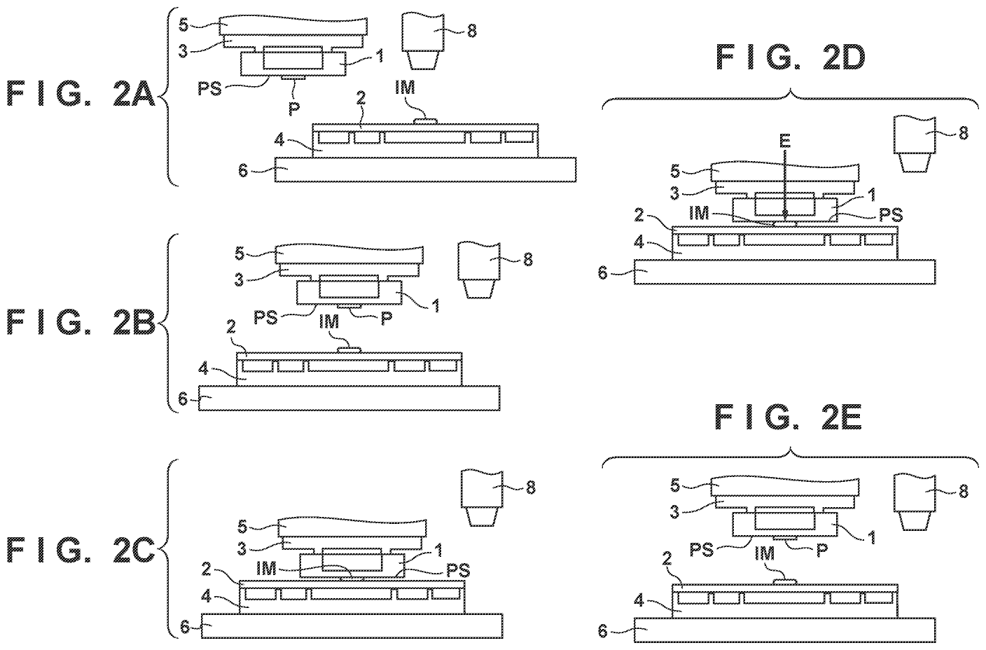

FIGS. 2A, 2B, 2C, 2D, and 2E are views schematically illustrating respective processes of the imprint process under the control of the control unit CNT. The imprint process includes an arrangement process, a contact process (filling process), a curing process, and a separation process. In this embodiment, the imprint process includes the arrangement process of arranging the imprint material IM on the substrate 2 but the arrangement process may be executed by another apparatus.

In the arrangement process, as shown in FIG. 2A, the arrangement mechanism 8 arranges the imprint material IM on one or a plurality of shot regions of the substrate 2. Next, as shown in FIG. 2B, the mold driving mechanism 5 and the substrate driving mechanism 6 are controlled so that the mold 1 and a shot region, as a pattern formation target, of the substrate 2 are aligned. Next, in the contact step, as shown in FIG. 2C, the mold driving mechanism 5 and the substrate driving mechanism 6 are controlled so that the mold 1 and the imprint material IM on the shot region, as the pattern formation target, of the substrate 2 are brought into contact with each other. The contact process includes the filling process of filling, with the imprint material IM, the concave portion that defines the pattern P of the mold 1.

Next, in the curing process, as shown in FIG. 2D, the curing unit 14 irradiates the imprint material IM under the pattern P of the mold 1 with curing energy E. This cures the imprint material IM on the shot region of the substrate 2, thereby forming a pattern made of a cured product of the imprint material IM.

Next, in the separation process, as shown in FIG. 2E, the mold driving mechanism 5 and the substrate driving mechanism 6 are controlled so that the mold 1 (the pattern P thereof) and the pattern made of the cured product of the imprint material IM on the shot region of the substrate 2 are separated. Thus, the pattern separated from the mold 1 remains on the shot region of the substrate 2. In the separation process, at least one of the substrate 2 and the mold 1 is driven so that the substrate 2 and the mold 1 are released against a bonding force between the mold 1 (the pattern P thereof) and the pattern made of the cured product of the imprint material IM on the substrate.

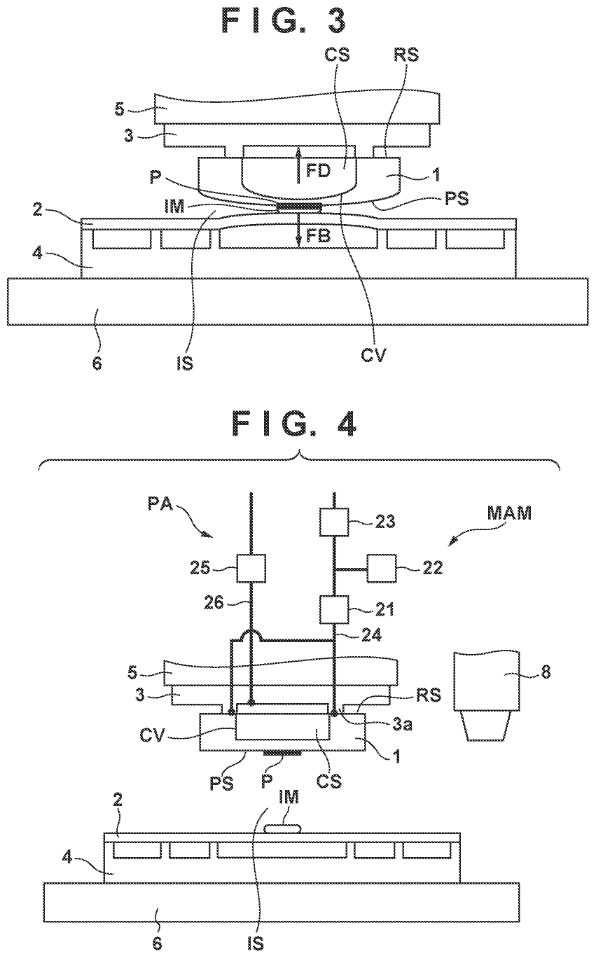

FIG. 3 is a view schematically illustrating forces acting in the separation step shown in FIG. 2E. If at least one of the substrate 2 and the mold 1 is driven by a driving force FD so that the substrate 2 and the mold 1 are released, drag (reaction) is generated in the opposite direction of the driving force FD between the cured product of the imprint material IM on the substrate and the pattern P of the mold 1. If the driving force FD (drag) exceeds a bonding force FB between the cured product of the imprint material IM and the pattern P of the mold 1, the cured product of the imprint material IM and the pattern P of the mold 1 are separated. Drag is also generated between the mold holding unit 3 (mold holding surface MS) and the mold 1, between the substrate holding unit 4 (substrate holding surface SS) and the substrate 2, and between the substrate 2 and the cured product of the imprint material IM. If the driving force FD (drag) exceeds the holding force (suction force) of the mold holding unit 3, so-called dechucking that the mold 1 is detached (comes off) from the mold holding unit 3 occurs.

The substrate holding unit 4 (substrate holding surface SS) includes a plurality of suction units independent of each other, as will be described later. In a state in which the plurality of suction units of the substrate holding unit 4 are controlled, the separation process is performed so that the shot region as the target of the imprint process (separation process) is allowed to have a convex shape toward the mold 1.

In the separation process, the bonding force FB may become larger than the holding force of the mold 1 by the mold holding unit 3 due to various factors such as the material composition of the imprint material IM, the surface states of the mold 1 and the substrate 2, and suction forces of the substrate holding unit 4 and the mold holding unit 3. In this case, the separation process is not normally performed, a gap is generated between the mold holding unit 3 (mold holding surface MS) and the mold 1, and dechucking that the mold 1 is detached from the mold holding unit 3 occurs, as described above. If dechucking occurs, a recovery process for recovering (returning) to a normal state is necessary.

The recovery process of dechucking includes, for example, a process of performing the separation process by driving (lowering) the mold holding unit 3 to the substrate side to hold again the mold 1 and increasing the holding force of the mold 1 by the mold holding unit 3. Note that in a state in which the mold 1 is dechucked, that is, in a state in which the mold 1 exists on the substrate, the substrate 2 may be unloaded from the imprint apparatus 100 and the mold 1 may be separated from the cured product of the imprint material IM on the substrate.

Note that in a case where it is impossible to recover to the normal state even by performing such complicated recovery process, it may be necessary to stop the imprint apparatus 100 and perform a recovery operation manually by an operator.

As described above, if dechucking occurs, it takes long time to recover the imprint apparatus 100 to the normal state and the productivity of the imprint apparatus 100 decreases. Therefore, to maintain the productivity of the imprint apparatus 100, it is preferable to prevent occurrence of dechucking that the mold 1 is detached from the mold holding unit 3.

In this embodiment, the control unit CNT predicts whether the separation process is complete while the separation process is performed against the bonding force between the mold 1 and the pattern made of the cured product of the imprint material IM on the substrate. Then, if it is predicted that the separation process is not complete, the control unit CNT controls adjustment, by the pressure adjusting mechanism PA, of the pressure difference between the pressure in the imprint space IS and the pressure on the surface RS of the mold 1, that is, the pressure in the cavity space CS so that the separation process is complete.

FIG. 4 is a view illustrating the arrangement of a mold suction mechanism MAM and the pressure adjusting mechanism PA in the imprint apparatus 100. The mold suction mechanism MAM includes the mold holding unit 3 driven by the mold driving mechanism 5, more specifically, a vacuum line 24 connected to the ring-shaped projecting portion 3a (suction portion). The mold suction mechanism MAM further includes a pressure sensor 22 that detects a pressure in the vacuum line 24, a flow rate sensor 21 that detects a flow rate of a gas flowing through the vacuum line 24, and a pressure adjusting unit 23. The pressure adjusting unit 23 is arranged between the vacuum line 24 and a vacuum source (not shown), and adjusts the pressure in the vacuum line 24 under the control of the control unit CNT. Information representing the pressure detected by the pressure sensor 22 and information representing the flow rate detected by the flow rate sensor 21 are provided to the control unit CNT to generate a pressure command value and an opening command value. The pressure adjusting unit 23 adjusts the pressure in the vacuum line 24 in accordance with the pressure command value and the opening command value from the control unit CNT.

The pressure adjusting mechanism PA has a function of adjusting (modulating) the pressure in the cavity space CS by increasing or decreasing the pressure in the cavity space CS. The pressure adjusting mechanism PA includes a pressure adjusting unit 25 that includes a positive pressure valve and a negative pressure valve, and a pressure control line 26 that connects the pressure adjusting unit 25 and the cavity space CS. The pressure adjusting unit 25 is arranged between the pressure control line 26 and a pressure source (not shown), and accurately adjusts the pressure in the cavity space CS by adjusting the pressure in the pressure control line 26 under the control of the control unit CNT.

For example, in the contact process of bringing the mold 1 and the imprint material IM on the substrate into contact with each other, the control unit CNT controls the pressure adjusting mechanism PA so that the pressure adjusting unit 25 increases the pressure in the cavity space CS via the pressure control line 26. More specifically, the pressure adjusting mechanism PA applies a positive pressure of 20 kPa to 30 kPa to the cavity space CS under the control of the control unit CNT. This can adjust the pressure in the cavity space CS to a pressure higher than that in the imprint space IS, thereby deforming the pattern P of the mold 1 into a convex shape toward the substrate 2. Note that the numerical value of the positive pressure applied to the cavity space CS by the pressure adjusting mechanism PA is merely an example, and can be set within a range in which the mold 1 (the pattern P thereof) is not damaged by deformation.

If it is predicted that the separation process of separating the mold 1 from the pattern made of the cured product of the imprint material IM on the substrate is not complete, the control unit CNT controls the pressure adjusting mechanism PA so that the pressure adjusting unit 25 decreases the pressure in the cavity space CS via the pressure control line 26. More specifically, the pressure adjusting mechanism PA applies a negative pressure of −20 kPa to −30 kPa to the cavity space CS under the control of the control unit CNT. This adjusts the pressure in the cavity space CS to a pressure lower than that in the imprint space IS, and the pressure difference applies, to the mold 1, a force in the same direction as that of the holding force of the mold 1 by the mold holding unit 3. Therefore, even in a case where the bonding force between the mold 1 (the pattern P thereof) and the pattern made of the cured product of the imprint material IM on the substrate is relatively strong and it is predicted that the separation process is not complete, it is possible to complete the separation process while preventing occurrence of dechucking that the mold 1 is detached from the mold holding unit 3. Note that the numerical value of the negative pressure applied to the cavity space CS by the pressure adjusting mechanism PA is merely an example, and can be set within a range in which the mold 1 (the pattern P thereof) is not damaged by deformation.

In this embodiment, whether the separation process is complete can be predicted based on a state quantity generated while the separation process is performed. As the state quantity, for example, a state quantity concerning a mold positioning mechanism AM of the mold driving mechanism 5 that positions the mold 1 (mold holding unit 3) in accordance with a command value such as a position command value from the control unit CNT can be used.

FIG. 5 is a view illustrating the arrangement of the mold positioning mechanism AM of the mold driving mechanism 5. As shown in FIG. 5, the mold positioning mechanism AM is configured to perform feedback control of the position of the mold 1 (mold holding unit 3) in accordance with a position command value TP from the control unit CNT. However, the mold positioning mechanism AM may be configured to perform feedforward control of the position of the mold 1 (mold driving mechanism 5) in accordance with the position command value from the control unit CNT.

The mold positioning mechanism AM includes a calculator 201, a compensator 202, a driver 203, an actuator 204, and a sensor 205. The calculator 201 calculates a deviation ER between the position command value TP and an output from the sensor 205, and provides it to the compensator 202. The compensator 202 generates a manipulated variable MV (for example, a current command value or a voltage value) based on the deviation ER, and provides it to the driver 203. The driver 203 drives the actuator 204 to generate a driving force according to the manipulated variable MV. The actuator 204 includes, for example, a voice coil motor or a piezoelectric element, and drives the mold driving mechanism 5 by the driving force according to the manipulated variable MV. The sensor 205 detects the position of the mold 1 held by the mold holding unit 3, and provides information representing the position to the calculator 201. However, the mold positioning mechanism AM may be configured to perform feedforward control of the position of the mold 1 (mold driving mechanism 5) in accordance with the position command value from the control unit CNT.

The control unit CNT acquires, for example, pieces of information from the pressure sensor 22, the flow rate sensor 21, and the compensator 202 as information representing the state quantity (the state quantity generated in the mold 1 (mold driving mechanism 5)) concerning the mold positioning mechanism AM while the separation process is performed. Based on at least one of these pieces of information, the control unit CNT predicts whether the separation process is complete.

In a case where the output from the pressure sensor 22, that is, the pressure in the vacuum line 24 is used as the state quantity, if the pressure detected by the pressure sensor 22 is higher than a first reference value (that is, the pressure is closer to the atmospheric pressure than the first reference value), the control unit CNT predicts that the separation process is not complete. In this example, when the pressure in the vacuum line 24 is higher than the first reference value, this means that the bonding force between the mold 1 (the pattern P thereof) and the pattern made of the cured product of the imprint material IM on the substrate is large and the suction force of the mold holding unit 3 is insufficient. Therefore, a gap is generated between the mold holding unit 3 (mold holding surface MS) and the mold 1, the possibility that air flows into the vacuum line 24 is high, and thus it can be predicted that the separation process is not complete.

In a case where the output from the flow rate sensor 21, that is, the flow rate of the gas flowing into the vacuum line 24 is used as the state quantity, if the flow rate detected by the flow rate sensor 21 is higher than a second reference value (that is, the flow rate is larger than the second reference value), the control unit CNT predicts that the separation process is not complete. When the flow rate of the gas flowing into the vacuum line 24 is higher than the second reference value, this means that the bonding force between the mold 1 (the pattern P thereof) and the pattern made of the cured product of the imprint material IM on the substrate is large and the suction force of the mold holding unit 3 is insufficient. Therefore, a gap is generated between the mold holding unit 3 (mold holding surface MS) and the mold 1, the possibility that air flows into the vacuum line 24 is high, and thus it can be predicted that the separation process is not complete.

In a case where a driving force generated in the actuator 204 by the output (manipulated variable MV) from the compensator 202 is used as the state quantity, if the output (driving force) from the compensator 202 is higher than a third reference value, the control unit CNT can predict that the separation process is not complete. Furthermore, if the control unit CNT integrates the driving force as the output from the compensator 202 with the time, and the thus obtained integrated value exceeds a fourth reference value, it is considered to require long time for the separation process, and thus it can be predicted that the separation process is not complete.

Furthermore, in this embodiment, to complete the separation process, the pressure difference between the pressure in the cavity space CS and the pressure in the imprint space IS dechunked is adjusted so that the pressure in the cavity space CS is lower than the pressure in the imprint space IS. However, when one or a plurality of processes to be described below are simultaneously performed, it is possible to further prevent occurrence of dechucking that the mold 1 is detached from the mold holding unit 3, and this is advantageous in completing the separation process.

More specifically, the control unit CNT performs a process of changing the control of the pressure adjusting unit 23 so as to decrease the pressure in the vacuum line 24, that is, to increase the suction force of the mold holding unit 3. The pressure adjusting unit 23 is controlled by controlling the command value provided to the pressure adjusting unit 23. Since this increases the holding force (suction force) of the mold 1 by the mold holding unit 3 (mold holding surface MS), it is possible to reduce the possibility of occurrence of dechucking in the separation process.

In addition, the control unit CNT may perform a process of controlling the mold driving mechanism 5 so as to decrease the speed of releasing the substrate 2 and the mold 1. For example, the control unit CNT may control the mold driving mechanism 5 to decrease the speed of raising the mold 1, or control the substrate driving mechanism 6 to decrease the speed of lowering the substrate 2. Thus, it is possible to reduce the possibility of occurrence of dechucking in the separation process.

The control unit CNT may perform a process of controlling the mold driving mechanism 5 and/or the substrate driving mechanism 6 to change the orientation of at least one of the mold 1 and the substrate 2. This can reduce the possibility of occurrence of dechucking in the separation process. Note that when changing the orientation of at least one of the mold 1 and the substrate 2, the orientation concerning at least one of the θX-axis and the θY-axis is preferably changed to suppress damage to the mold 1 or the pattern made of the cured product of the imprint material IM.

The control unit CNT may perform a process of controlling the mold pressing mechanism 11 to increase a force for pressing the side surfaces (for example, two side surfaces facing each other or four side surfaces) of the mold 1 by the mold pressing mechanism 11. Since this increases the holding force of the side surfaces of the mold 1 by the mold pressing mechanism 11, it is possible to suppress the mold 1 from dropping from the mold holding unit 3, and to reduce the possibility of occurrence of dechucking in the separation process.

From a viewpoint of adjusting the pressure in the cavity space CS to a pressure higher than that in the imprint space IS, it is usable to increase the pressure in the imprint space IS in addition to or instead of decreasing the pressure in the cavity space CS.

For example, a force (separation force) generated while the separation process is performed is the sum of a removing force and an air pressure caused by an instantaneous separation operation in the separation process. The removing force is a force of removing the mold 1 against the bonding force between the mold 1 (the pattern P thereof) and the pattern made of the cured product of the imprint material IM on the substrate. The air pressure is a force generated when the pressure in the imprint space IS becomes negative with respect to its periphery due to a sudden change in volume of the imprint space IS caused the separation operation, that is, a volumetric expansion change, and is a force acting in a direction in which separation of the mold 1 from the imprint material IM is impeded. Therefore, in the separation process, a decrease in the air pressure decreases the separation force, thereby reducing the possibility of occurrence of dechucking that the mold 1 is detached from the mold holding unit 3.

Therefore, the pressure in the imprint space IS is increased in accordance with the occurrence of a negative pressure caused by a sudden volumetric expansion change in the imprint space IS caused by the separation operation (that is, in accordance with a change in pressure in the imprint space IS). In this embodiment, the separation force is decreased by applying a positive pressure whose magnitude is almost equal to that of the negative pressure generated in the imprint space IS in the separation process so as to cancel (compensate) a change in pressure in the imprint space IS caused by the separation operation. Since this adjusts the pressure difference between the pressure in the space (cavity space CS) on the side of the surface RS of the mold 1 and the pressure in the imprint space IS so that the pressure in the cavity space CS is lower than that in the imprint space IS, it is possible to reduce the possibility of occurrence of dechucking in the separation process. Note that the negative pressure generated in the imprint space IS in the separation process can be acquired in advance by a simulation or an experiment, and information (a table) representing a positive pressure applied to the imprint space IS in accordance with the negative pressure is stored in the memory of the control unit CNT or the like.

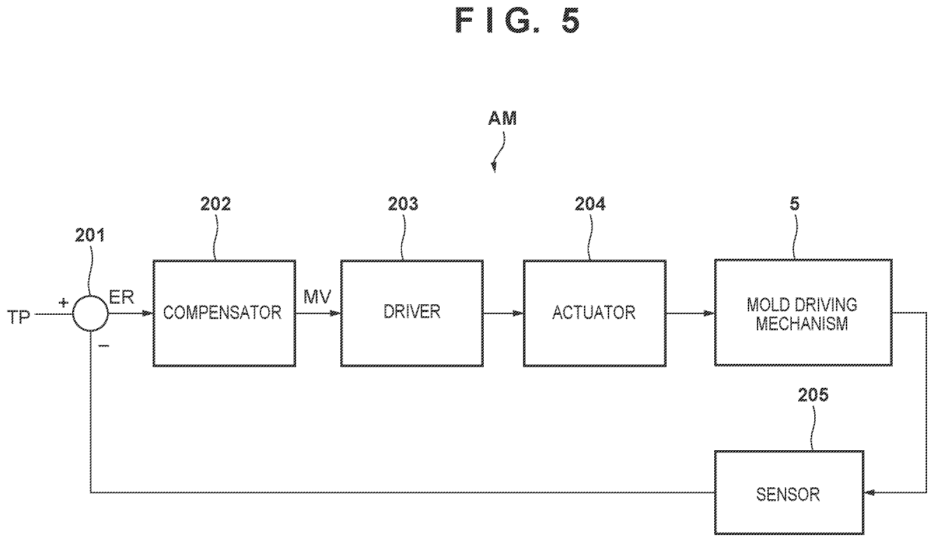

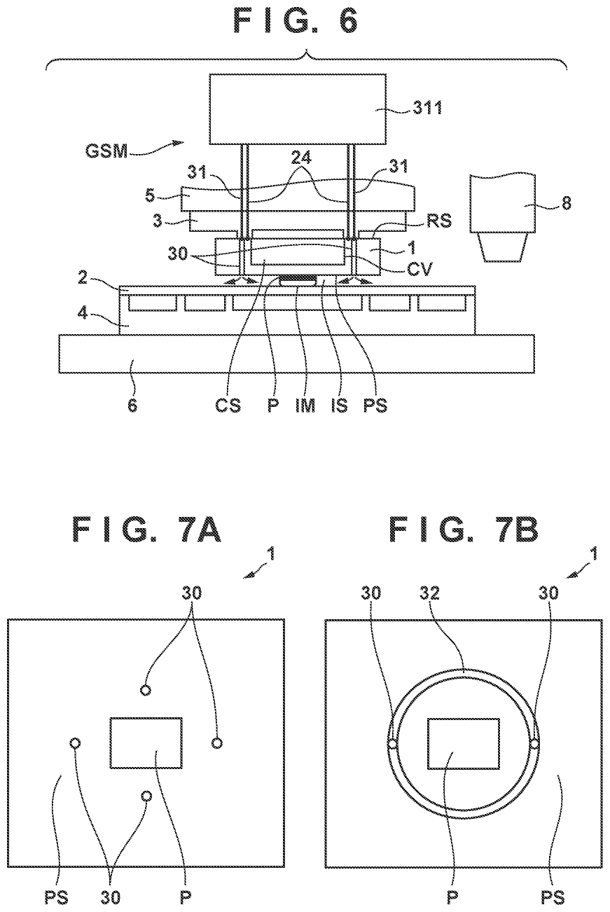

As the detailed arrangement of increasing the pressure in the imprint space IS, a gas supply mechanism GSM for supplying a gas to the imprint space IS is considered, as shown in FIG. 6. The gas supply mechanism GSM is controlled by the control unit CNT in the separation process to supply a pressurized gas to the imprint space IS. Therefore, the gas supply mechanism GSM functions as one adjusting unit that adjusts the pressure difference between the pressure in the space on the side of the surface RS of the mold 1 and the pressure in the imprint space IS. Note that as the gas supplied by the gas supply mechanism GSM to the imprint space IS, a gas such as air, nitrogen, or helium, a functional gas having a function of reducing a defect of the pattern formed on the substrate by the imprint process, a mixed gas thereof, or the like is used. FIG. 6 is a view illustrating the arrangement of the gas supply mechanism GSM that supplies a gas to the imprint space IS.

As shown in FIG. 6, the gas supply mechanism GSM includes a gas supply source 311, and a supply line 31 provided in the mold holding unit 3. The supply line 31 is a gas introducing portion that connects the gas supply source 311 and a hole 30 formed in the mold 1 and communicating with the imprint space IS. The gas supply mechanism GSM supplies (distributes) the gas from the gas supply source 311 to the imprint space IS via the supply line 31 and the hole 30. In this embodiment, the hole 30 is formed as a through hole extending through the mold 1 between the pattern surface PS of the mold 1 and the surface RS of the mold 1 but need only be a hole communicating with the imprint space IS. For example, the hole 30 can also be formed to be connected to the supply line 31 on the side surface of the mold 1. The gas supply mechanism GSM supplies the pressurized gas to the imprint space IS so that the imprint space IS is a substantially uniform partially pressurized space at the time of separation process under the control of the control unit CNT.

Note that to efficiently introduce the gas supplied from the gas supply mechanism GSM to the imprint space IS, a plurality of holes 30 are preferably formed in the pattern surface PS of the mold 1 to surround the pattern P of the mold 1, as shown in FIG. 7A. In this case, the gas from the gas supply source 311 is introduced to the supply line 31, and supplied to the imprint space IS via the plurality of holes 30. Furthermore, to more efficiently introduce the gas supplied from the gas supply mechanism GSM to the imprint space IS, a channel 32 communicating with the plurality of holes 30 is preferably provided in the pattern surface PS of the mold 1, as shown in FIG. 7B. In this case, the gas from the gas supply source 311 is introduced to the supply line 31, and supplied to the imprint space IS via the plurality of holes 30 and the channel 32. Note that for example, the channel 32 is larger than a shot region on the substrate and is provided to surround the pattern P of the mold 1. The channel 32 is formed as a concave portion in the pattern surface PS of the mold 1, and has an arbitrary sectional shape such as a circular shape or a rectangular shape. FIGS. 7A and 7B are views each illustrating the pattern surface PS of the mold 1 in which the plurality of holes 30 or the plurality of holes 30 and the channel 32 are provided.

For example, the gas supplied from the gas supply mechanism GSM to the imprint space IS may be discharged outside the imprint space IS along the pattern surface PS of the mold 1 and the surface of the substrate 2. Furthermore, the gas discharged outside the imprint space IS may be discharged outside the imprint apparatus 100 by the environment management unit 7.

The pattern of a cured product formed using the imprint apparatus 100 (imprint method) is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, a SRAM, a flash memory, and a MRAM and semiconductor elements such as an LSI, a CCD, an image sensor, and an FPGA. Examples of the mold are molds for imprint.

The pattern of the cured product is directly used as the constituent member of at least some of the above-described articles or used temporarily as a resist mask. After etching or ion implantation is performed in the substrate processing step, the resist mask is removed.

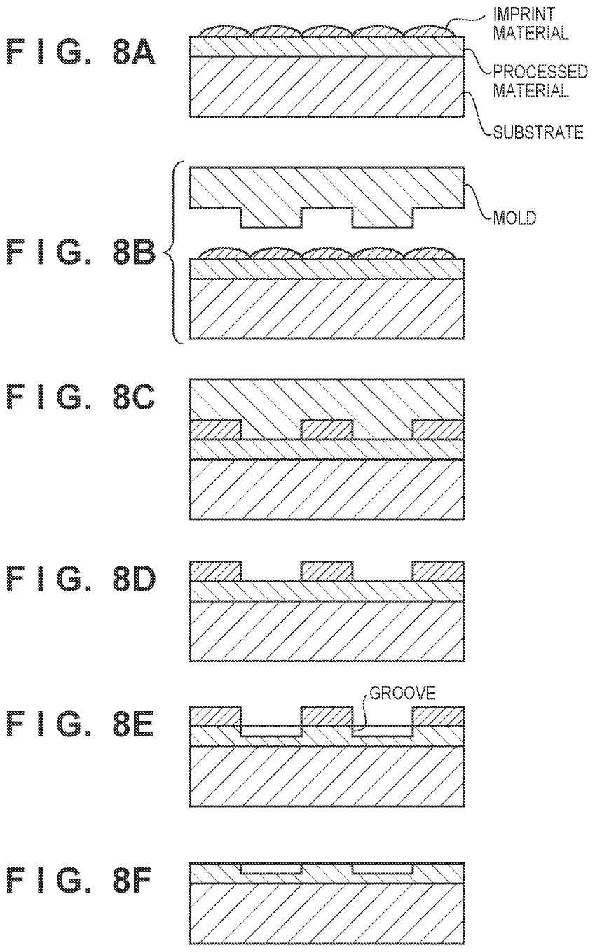

Next, description regarding a detailed method of manufacturing an article is given. As illustrated in FIG. 8A, the substrate such as a silicon wafer with a processed material such as an insulator formed on the surface is prepared. Next, an imprint material is applied to the surface of the processed material by an inkjet method or the like. A state in which the imprint material is applied as a plurality of droplets onto the substrate is shown here.

As shown in FIG. 8B, a side of the mold for imprint with a projection and groove pattern is formed on and caused to face the imprint material on the substrate. As illustrated in FIG. 8C, the substrate to which the imprint material is applied is brought into contact with the mold, and a pressure is applied. The gap between the mold and the processed material is filled with the imprint material. In this state, when the imprint material is irradiated with light serving as curing energy through the mold, the imprint material is cured.

As shown in FIG. 8D, after the imprint material is cured, the mold is released from the substrate. Thus, the pattern of the cured product of the imprint material is formed on the substrate. In the pattern of the cured product, the groove of the mold corresponds to the projection of the cured product, and the projection of the mold corresponds to the groove of the cured product. That is, the projection and groove pattern of the mold is transferred to the imprint material.

As shown in FIG. 8E, when etching is performed using the pattern of the cured product as an etching resistant mask, a portion of the surface of the processed material where the cured product does not exist or remains thin is removed to form a groove. As shown in FIG. 8F, when the pattern of the cured product is removed, an article with the grooves formed in the surface of the processed material can be obtained. The pattern of the cured material is removed here, but, for example, the pattern may be used as a film for insulation between layers included in a semiconductor element or the like without being removed after processing, in other words as a constituent member of the article.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent application No. 2022-208799 filed on Dec. 26, 2022, which is hereby incorporated by reference herein in its entirety.

What is claimed is:

1. An imprint apparatus for performing an imprint process of forming a pattern made of a cured product of an imprint material on a substrate using a mold, comprising:
a mold holding unit configured to hold the mold;
an adjusting unit configured to adjust a pressure difference between a first pressure on a second surface on an opposite side of a first surface on which a pattern of the mold held by the mold holding unit is formed and a second pressure in a first space between the substrate and the first surface of the mold; and
a control unit configured to control the imprint process,
wherein the imprint process includes a separation process of separating the mold from the pattern made of the cured product of the imprint material, and
the control unit controls, in the separation process, the adjustment of the pressure difference by the adjusting unit so that the first pressure is smaller than the second pressure.

2. The apparatus according to claim 1, wherein the control unit predicts whether the separation process is complete while the separation process is performed, and controls, in a case where it is predicted that the separation process is not complete, the adjustment of the pressure difference by the adjusting unit so that the separation process is completed.

3. The apparatus according to claim 1, wherein the control unit controls the adjustment of the pressure difference by the adjusting unit so that the first pressure is smaller than the second pressure by decreasing a pressure in a second space on a side of the second surface of the mold.

4. The apparatus according to claim 3, wherein
the mold holding unit includes a mold holding surface configured to hold the second surface of the mold,
a concave portion having a concave shape is formed in the second surface of the mold to deform the first surface into a convex shape toward the substrate,
the second space is a space defined by the mold holding surface and the concave portion,
the adjusting unit includes a pressure adjusting mechanism configured to adjust the pressure in the second space, and
the control unit controls the adjusting unit in the separation process so that the pressure adjusting mechanism decreases the pressure in the second space.

5. The apparatus according to claim 4, wherein
the imprint process includes a contact process of bringing the imprint material on the substrate and the mold into contact with each other, and
the control unit controls the adjusting unit in the contact process so that the pressure adjusting mechanism increases the pressure in the second space.

6. The apparatus according to claim 1, wherein the control unit controls the adjustment of the pressure difference by the adjusting unit so that the first pressure is smaller than the second pressure by increasing the pressure in the first space.

7. The apparatus according to claim 6, wherein
the adjusting unit includes a gas supply mechanism configured to supply a gas to the first space, and
the control unit controls the adjusting unit in the separation process so that the gas supply mechanism supplies a pressurized gas to the first space.

8. The apparatus according to claim 7, wherein the control unit controls the adjusting unit so that the gas supply mechanism supplies the pressurized gas to the first space in accordance with a change in the pressure in the first space caused by a change in a volume of the first space while separation process is performed.

9. The apparatus according to claim 8, wherein the control unit controls the adjusting unit so as to cancel, by supplying the pressurized gas to the first space by the gas supply mechanism, the change in the pressure in the first space caused by the change in the volume of the first space while separation process is performed.

10. The apparatus according to claim 7, wherein
a hole communicating with the first space is formed in the mold, and
the gas supply mechanism supplies the pressurized gas to the first space via the hole.

11. The apparatus according to claim 10, wherein the hole includes a through hole extending through the mold between the first surface and the second surface.

12. The apparatus according to claim 7, wherein
a plurality of holes communicating with the first space and a channel communicating with the plurality of holes in the first surface are provided in the mold, and
the gas supply mechanism supplies the pressurized gas to the first space via the plurality of holes and the channel.

13. The apparatus according to claim 2, wherein the control unit predicts whether the separation process is complete, based on a state quantity generated while the separation process is performed against a bonding force between the mold and the pattern made of the cured product of the imprint material.

14. An imprint method of forming a pattern made of a cured product of an imprint material on a substrate using a mold, comprising:
adjusting, in a separation process of separating the mold from the pattern made of the cured product of the imprint material, a pressure difference between a first pressure on a second surface on an opposite side of a first surface on which a pattern of the mold is formed and a second pressure in a first space between the substrate and the first surface of the mold,
in the adjusting, the adjustment of the pressure difference is controlled so that the first pressure is smaller than the second pressure.

15. An article manufacturing method comprising:
forming a pattern on a substrate using an imprint method defined in claim 14;
processing the substrate on which the pattern is formed in the forming; and
manufacturing an article from the processed substrate.
